(19) United States
(12) Patent Application Publication
(10) Pub. No.: US 2005/0068731 A1
(43) Pub. Date: Mar. 31, 2005

(54) Hot-swap fan module configuration

(76) Inventor: Wen Wei, Beaverton, OR (US)

Correspondence Address: SCHWABE, WILLIAMSON & WYATT, P.C.;PACWEST CENTER, SUITES 1600-1900, 1211 SW FIFTH AVENUE, PORTLAND, OR, 97204, US

(21) Appl. No.: 10/748,309

(22) Filed: Dec. 29, 2003

Related U.S. Application Data
(60) Provisional application No. 60/507,221, filed on Sep. 29, 2003.

(51) Int. Cl. H05K 7/20

(52) U.S. Cl. 361/695

(57) ABSTRACT

A modular platform cooling apparatus is provided. The modular platform cooling apparatus includes at least one plenum associated with the apparatus and a first and a second fan module configured to removably and independently engage the plenum.

### RELATED APPLICATIONS

This application claims the benefit of U.S. Provisional Application No. 60/507,221, filed on Sep. 29, 2003.

### FIELD OF THE INVENTION

Embodiments of the invention generally relate to modular computing systems such as, systems in accordance or in compliance with the specification of the Advanced Telecom Computing Architecture (ATCA). More specifically, disclosed embodiments of the invention relate to an airflow cooling apparatus and methods to enhance heat removal from a modular platform.

### BRIEF DESCRIPTION OF THE DRAWINGS

The invention is illustrated by way of example and not by way of limitation in the figures of the accompanying drawings, in which the like references indicate similar elements and in which:

FIG. 1 illustrates a side perspective view of a modular platform in accordance with an embodiment of the present invention;

FIG. 2 illustrates an enlarged view of a fan module of FIG. 1 in accordance with an embodiment of the present invention;

FIG. 3 illustrates an enlarged view of a modular platform fan module in accordance with an embodiment of the present invention; and

FIG. 4 illustrates a rear perspective view of a modular platform in accordance with an embodiment of the present invention.

### DETAILED DESCRIPTION OF EMBODIMENTS OF THE INVENTION

In the following detailed description, reference is made to the accompanying drawings that form a part hereof wherein like numerals designate like parts throughout, and in which is shown by way of illustration specific embodiments in which the invention may be practiced. It is to be understood that other embodiments may be utilized and structural or logical changes may be made without departing from the scope of the present invention. Therefore, the following detailed description is not to be taken in a limiting sense, and the scope of the present invention is defined by the appended claims and their equivalents.

Embodiments of the present invention may provide for more effective and reliable cooling of modular platforms, by affirmatively managing the heat generated by a plurality of modular platform boards having heat generating components. To effectively maintain a desired temperature range within a modular platform and across a modular platform board, a plurality of fans may be used to promote forced convection of the heat from the boards to a cooling medium. In several applications, such as Advanced Telecom Computing Architecture (ATCA) and Flexi-Server applications where modular platform space may be constrained, the fans must be sufficiently powerful, reliable, and easily interchangeable without disrupting the operation of the modular platform, as well as not substantially affecting the reliability of the modular platform boards.

Embodiments of the present invention provide fan modules that are readily and independently replaceable without significantly disrupting the modular platform airflow and thus the cooling of the modular platform boards.

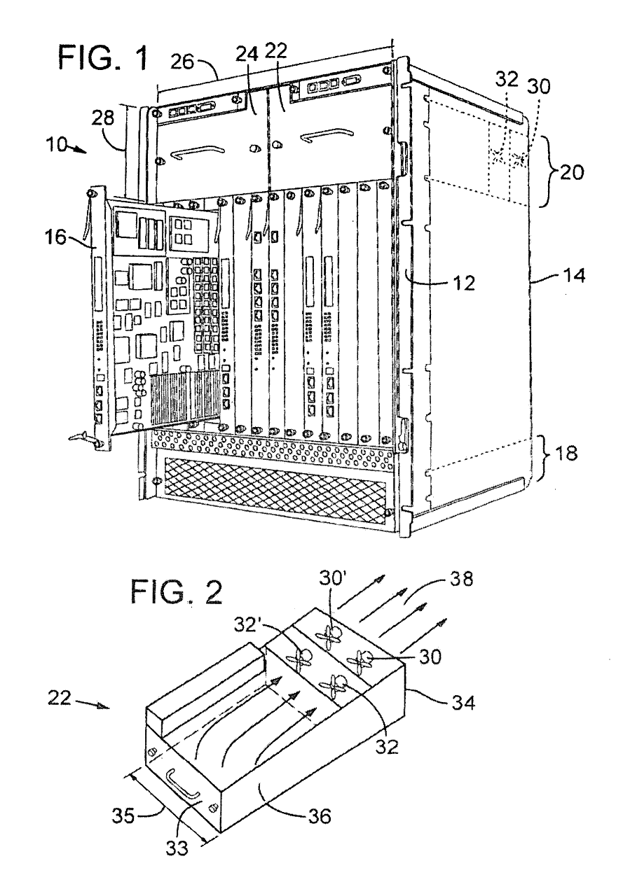

FIG. 1 illustrates a side perspective view of a modular platform 10 in accordance with an embodiment of the present invention. Modular platform 10 may have a front end 12 and a rear end 14 and may be configured to house a plurality of modular platform boards 16. Modular platform board 16 may contain several electronic components, including, but not limited to, semiconductor devices like microprocessors, memory and the like, as well as a host of nonsemiconductor type devices such as capacitors, diodes, transistors, and the like. Many of these electronic components, particularly the microprocessors, tend to generate a significant amount of heat. Certain modular platform boards and associated electronic components can generate over 200 Watts that must be affirmatively managed.

To effectively cool modular platform boards 16, modular platform 10 may include an intake plenum 18 and an exhaust plenum 20. A plurality of fans 30, 32 may act to force air or other cooling medium from outside the modular platform 10 through intake plenum 18, past modular platform boards 16 and out again through exhaust plenum 20. In doing so, heat generated from the modular platform boards 16 may be transferred to the passing cooling medium through forced convection.

Many specifications and design requirements require the cooling of modular platform boards to keep the temperature increase across a board to a certain maximum in order to ensure sustainable operating conditions. One such standard is the PCI Industrial Computer Manufacturers Group (PICMG) 3.0 ATCA Specification (ATCA Specification), which is targeted to the next generation of carrier grade communication equipment. The ATCA specification requires, for example, that a modular platform be equipped with up to sixteen slots that can accommodate up to sixteen modular platform boards. Each slot must be able to carry a modular platform board capable of generating up to 200 Watts of power, which results in a maximum thermal generation per modular platform of 3200 Watts. The ATCA Specification further requires that given these thermal generation requirements, any one modular platform board cannot endure more than a 10 degree Celsius temperature increase across the modular platform board at any given time. And, for purposes of reducing down time and operator accessibility, the fan module is required to be removable from the front side of the modular platform.

To effectively meet such a rigorous standard, current modular platforms, such as ATCA shelves, use a front side accessible fan module that has three fans in a side-by-side configuration and each of the three fans being redundant, or two deep, for a total of six fans. If a fan were to go down, the entire fan module must be removed from the modular platform and a new fan module inserted in its place. Because modular platforms may be required to be kept operational while the fan module is removed and replaced (hot-swap), the time necessary to swap a fan module, even barring any problems during the swap, can substantially disrupt and may even stop the airflow through the modular platform. Such a disruption of airflow may cause the modular platform board components to overheat and potentially fail, as well as reduce the electronic component reliability and negatively impact the mean time to failure.

As seen in FIG. 1, an embodiment in accordance with the present inventions includes multiple fan modules that are front side accessible and allow continued airflow, despite the potential hot swap of one fan module. First fan module 22 and a second fan module 24 may work in concert to provide the necessary airflow through the modular platform 10 that may be sufficient to cool any number of modular platform boards 16, as required by a certain specification. First and second fan modules 22, 24 may independently engage plenum 20 and may be independently removable from plenum 20, even while the modular platform is operational.

First and second fan modules may have a plurality of fans arranged in a matrix array. The aggregate width of first and second fan modules 22, 24 may be less than or equal to an allowed aggregate width 26 of the modular platform itself. In the case of an ATCA shelf, the aggregate width 26 should be less than or equal to 440 mm.

If a fan in either fan module malfunctions, only one fan module need be replaced as opposed to the entire tray responsible for modular platform cooling. For example, if a fan 30 or 32 failed, the first fan module 22 may be removed from the exhaust plenum 20 through the front side 12 of the modular platform 10 and replaced. While first fan module 22 is removed, second fan module 24 may continue to operate. Second fan module 24 can continue to force air through the modular platform 10, and thus continue to provide a reduced degree of airflow, which may result in continued cooling of the modular platform boards 16.

FIG. 2 illustrates an enlarged view of a fan module of FIG. 1 in accordance with an embodiment of the present invention. Fan module 22 may have a module front end 33 and a module rear portion 34, and may be configured to be removable from the modular platform (not shown). A plurality of fans 30, 30′, 32, and 32′ may be positioned at or near the rear portion 34 in an in-plane matrix array.

When operational, fans 30, 30′, 32, and 32′ may force air from the lower modular platform (not shown) through the bottom 36 of the fan module and out the rear portion 34, as shown by airflow arrows 38. As shown, fans 30, 30′, 32, and 32′ are in a particular matrix array, where fans 30 and 30′, and 32 and 32′ may be in a side-by-side relationship, respectively. Fans 30 and 32 may be redundant and in a rear-to-front relationship, or in series. Likewise, fans 30′ and 32′ may also be in a rear-to-front series.

It has been found that the distance between the fans in series, such as 30 to 32, can impact the performance of the fan modules and their ability to generate sufficient airflow for cooling the modular platform boards. To optimize fan performance and achieve substantially uniform airflow over the modular platform boards, as the diameter of the fan hub is decreased, the distance between the fans in series may be decreased. Accordingly, the spacing between rear-to-front fans may be a function of the diameter of the fan hub.

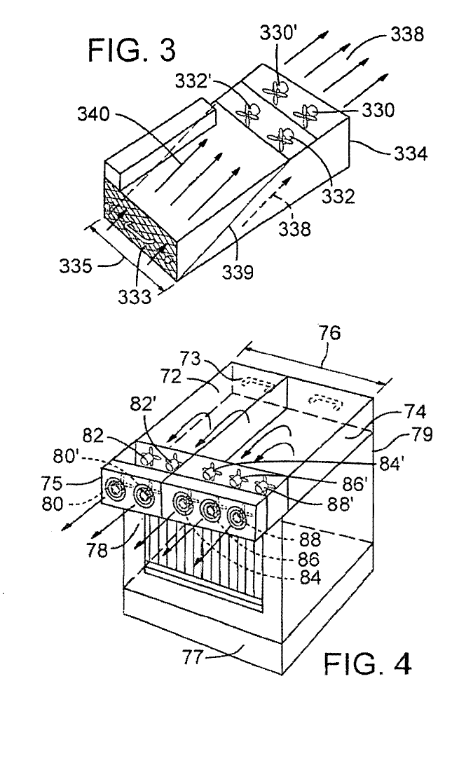

FIG. 3 illustrates an enlarged view of a modular platform fan module in accordance with an embodiment of the present invention. The fan module has a matrix array of fans 330, 330′, 332, and 332′ that may assist in cooling a modular platform. The fan module has a width 335 and includes a divider 339 that separates the fan module in an upper portion and a lower portion. A fan module of such a configuration may result in a dual plenum, such that the front or upper portion of the fan module could be used as an intake for a modular platform positioned above the fan module (not shown) and the rear or lower portion used for the exhaust of a modular platform positioned below. For an adjacent upper modular platform, intake airflow 340 may pass though grate 333. Shared plenum divider 339 would direct airflow 340 toward the upper fan module. Likewise, airflow 338 from the lower modular platform (not shown), would be directed by the baffle 339 out the rear portion 334 of the fan module.

Referring back to FIG. 1, oftentimes the operational features of a modular platform, such as modular platform boards, system management modules, and the like, may be required to be redundant, and in certain specifications, such as the ATCA Specification redundancy is required. Such redundancy may ensure that failure of one feature will not substantially disrupt the performance of the overall modular platform. Thus, where the total number of boards is m, typically only ½ m boards may be operational at any given time and generating heat that needs to be dispersed. Accordingly, where multiple fan modules are used, removal of one module will not necessarily reduce the cooling capacity by 50%. It has been found that where two fan modules are used, having symmetrically disposed fan configurations, the reduction in airflow was less than 30% across all the modular platform boards.

Additionally, to effectively cool modular platform boards 16, the flow profile of air pulled through the modular platform 10 by fan modules 22, 24 may be generally uniform across the modular platform boards. To enhance uniformity, the fan profile across the fan modules 22, 24 and thus the aggregate width 26 may be uniformly disposed in a matrix array. In such a configuration, the number of modular platform boards m that each fan module can fully support may be the same, or ½ m, where the number of trays is two. When one fan module is removed from the modular platform, the airflow profile may be temporarily nonuniform, but will resume uniformity once the fan module is replaced.

Fan modules in accordance with the present invention may also be asymmetrically configured such that each fan module may have a different number of fans in a side-by-side relationship, yet be uniformly disposed across the aggregate width. FIG. 4 illustrates an embodiment of a modular platform in accordance with the present invention where asymmetric fan modules are used. First fan module 72 has a front end 73 and a rear portion 75. A matrix array of fans may be positioned at the rear portion 75 of first fan module 72 and includes a 2×2 configuration of fans 80 and 80′, and 82 and 82′. Second fan module 74 includes a matrix array of fans at the rear portion that includes a 3×2 configuration, where fans 84, 86, and 88 are positioned side-by-side, and fans 84′, 86′, and 88′ are arranged side-by-side and correspondingly positioned behind fans 84, 86, and 88.

First fan module 72 and second fan module 74 are independent from one another and separately removable from the front side 79 of the modular platform. The aggregate width 76 of first fan module 72 and the second module 74 is less than or equal to the allowed width of the modular platform itself. In the case of an ATCA shelf, the aggregate width 76 should be less than or equal to 440 mm.

When in operation, the first fan module 72 and the second fan module 74 may provide enough airflow through the modular platform to support the cooling of the maximum number of boards in the modular platform (e.g., sixteen in ATCA) at the maximum thermal generation (e.g., 200 Watts per board and 3200 Watts per modular platform in ATCA).

As with the symmetric fan modules discussed above, asymmetric fan modules may be configured to support a certain number of modular platform boards. The number of modular platform boards that an individual fan module may support may be equal to (y/x) m, where m is the total number of potential modular platform boards, y is the number of side-by-side fans in the fan module, and x is the number of side-by-side fans from all modules that may be disposed across the aggregate width. Considering the example in FIG. 3, y equals three fans side-by-side, and x equals five fans side-by-side spanning the aggregate width 76. Accordingly, fan module 74 may support ⅗ m boards. Likewise, fan module 72 may support ⅖ m boards.

Where the fan modules are symmetrically configured in the number of fan units per module, such as 2×2, it has been found that even though each module may be configured to support a certain number of boards, with one fan module removed, the remaining module can support more boards at a reduced airflow rate, which has been found to be approximately 70%. The same may be true for asymmetric fan modules, such as the example embodiment shown in FIG. 3. The airflow rate may be even higher than 70% depending on which tray is removed. Accordingly, despite the reduced airflow rate when a fan module is removed, airflow still is induced and the modular platform boards may still transfer heat and resist overheating for longer periods of time.

Using the asymmetric configuration of FIG. 3 may allow for a plurality of smaller diameter fans to be used in the fan modules. By using a smaller diameter fan, the vertical dimension of the module may be less, which in turn may reduce the plenum size. Plenum size reduction may have benefits in certain Specifications, such as in the ATCA Specification. Existing telecom racks, in which ATCA shelves may be positioned, are typically 42 U in height, where 1 U is approximately equal to 44 mm. Having five fan units evenly distributed across the aggregate width 76 of the shelf allows use of fans having an overall diameter of approximately 88 mm, which is approximately 2 U. Thus, a plenum height may be 2 U, which has been found to allow for maximizing the use of rack space and allow for more flexibility in rack and individual shelf configurations.

Fan module embodiments in accordance with the present invention are hot swappable, in that one or more fan modules may be removed from the plenum while the other fan module(s) remain operational. To enable such a hot swap, redundant independent circuits for each fan module may be included to enable operation or inoperation by engaging or disengaging the fan module.

Though the illustrated embodiments in accordance with the present invention have shown only two fan module configurations, it can be appreciated that the number of fan modules may be more than two. Likewise, the number of fans in each matrix array may also be greater or less than those shown in the illustrated embodiments. Further, multifan module embodiments in accordance with the present invention may be used in the intake plenum. Where the fan modules are positioned in the intake plenum, the fans of the fan module may be positioned near the front portion of the fan module to force air through the modular platform and out the exhaust plenum.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

1. A modular platform cooling apparatus, comprising:
at least one plenum associated with the apparatus; and
a first and a second fan module configured to removably and independently engage the plenum.

2. The modular platform cooling apparatus of claim 1, wherein the first and second fan modules each include a plurality of fans arranged in a matrix array.

3. The modular platform cooling apparatus of claim 2, wherein at least one of the first and second fan modules includes a matrix array of four fans positioned in a 2-across by 2-deep in-plane relationship.

4. The modular platform cooling apparatus of claim 2, wherein at least one of the first and second fan modules has six fans positioned in a 3-across by 2-deep in-plane relationship.

5. The modular platform cooling apparatus of claim 2, wherein the fans have a center hub of a certain diameter and the fans positioned in the 2-deep relationship are separated by a distance that is proportional to and a function of the diameter of the hub.

6. The modular platform cooling apparatus of claim 1, wherein at least one of the first and second fan modules may be removed from the at least one plenum while the other fan module continues to provide airflow through a modular platform.

7. The modular platform cooling apparatus of claim 6 wherein the apparatus further comprises circuitry designed to allow the second fan module to be removably added to the apparatus while the apparatus, including the first fan module, is in operation.

8. The modular platform cooling apparatus of claim 6, wherein the first fan module is designed to provide sufficient airflow capacity to cool (y/x)m modular platform boards at a specified capacity, where y equals the total number of side-by-side fans in the first fan module and x equals the total number of fans positioned side by side across an aggregate width of the modular platform, and m equals the total number of modular platform boards.

9. The modular platform cooling apparatus of claim 8, wherein the first fan module will continue to provide airflow through the modular platform to support m modular platform boards and a capacity greater than 50% when the second fan module has been removed from the plenum.

10. The modular platform cooling apparatus of claim 1, wherein the first and the second fan modules, when operating in conjunction with the other, are designed to provide sufficient airflow to cool 2 m modular platform boards, where m equals the total number of modular platform boards.

11. The modular platform cooling apparatus of claim 1, wherein the modular platform is at least part compliant with a standard and includes:
a width dimension for the at least one plenum that is within a dimension requirement of the standard; and
a cooling performance that is within a modular platform board cooling requirement of the standard.

12. The modular platform cooling apparatus of claim 11, wherein the standard is PICMG 3.0 ATCA, and the width dimension requirement is less than or equal to 440 mm, and wherein the aggregate width of the first fan module and the second fan module is less than or equal to 440 mm.

13. The modular platform cooling apparatus of claim 12, wherein the standard is PICMG 3.0 ATCA, and the cooling requirement is maintaining a less than or equal to 10-degrees Celsius temperature increase per modular platform board, where each modular platform board can generate up to 200 Watts.

14. The modular platform cooling apparatus of claim 13, wherein the shelf has up to sixteen modular platform boards and the first fan module and the second fan module provide enough airflow to keep the temperature increase across any modular platform board to less than or equal to 10 degrees Celsius.

15. A Modular platform, comprising:
a plurality of modular platform boards;
at least one plenum coupled to the modular platform; and
a first and a second fan module configured to removably and independently engage the plenum.

16. The modular platform of claim 15, wherein the first and second fan modules each include a plurality of fans arranged in a matrix array.

17. The modular platform of claim 16, wherein at least one of the first and second fan modules includes a matrix array of four fans positioned in a 2-across by 2-deep in-plane relationship.

18. The modular platform of claim 16, wherein at least one of the first and second fan modules has six fans positioned in a 3-across by 2-deep in-plane relationship.

19. The modular platform of claim 16, wherein the fans have a center hub of a certain diameter and the fans positioned in the 2-deep relationship are separated by a distance that is proportional to and a function of the diameter of the hub.

20. The modular platform of claim 16, wherein at least one of the first and second fan modules may be removed from the at least one plenum while the other fan module continues to provide airflow through the modular platform.

21. The modular platform of claim 20, wherein the modular platform further comprises circuitry designed to allow the second fan module to be removably added to the apparatus while the modular platform, including the first fan module, is in operation.

22. The modular platform of claim 20, wherein the first fan module is designed to provide sufficient airflow capacity to cool (y/x)m modular platform boards at a specified capacity, where y equals the total number of side-by-side fans in the first fan module and x equals the total number of fans positioned side-by-side across an aggregate width of the modular platform, and m equals the total number of modular platform boards.

23. The modular platform of claim 22, wherein the first fan module will continue to provide airflow through the modular platform to support m modular platform boards and a capacity greater than 50% when the second fan module has been removed from the plenum.

24. The modular platform of claim 16, wherein the first and the second fan modules, when operating in conjunction with the other, are designed to provide sufficient airflow to cool 2 m modular platform boards, m equals the total number of modular platform boards.

25. The modular platform of claim 16, wherein the modular platform is at least part compliant with a standard and includes:
a width dimension for the at least one plenum that is within a dimension requirement of the standard; and
a cooling performance that is within a modular platform board cooling requirement of the standard.

26. The modular platform of claim 25, wherein the standard is PICMG 3.0 ATCA, and the width dimension requirement is less than or equal to 440 mm, and wherein the aggregate width of the first fan module and the second fan module is less than or equal to 440 mm.

27. The modular platform of claim 26, wherein the standard is PICMG 3.0 ATCA, and the cooling requirement is maintaining a less than or equal to 10-degrees Celsius temperature increase per modular platform board, where the modular platform board can generate in excess of 200 Watts.

28. The modular platform of claim 27, wherein the shelf has up to sixteen modular platform boards and the first fan module and the second fan module provide enough airflow to keep the temperature increase across any modular platform board to less than or equal to 10 degrees Celsius.

29. The modular platform of claim 16, wherein the modular platform includes an intake plenum and an exhaust plenum.

30. The modular platform of claim 29, wherein the first and second fan modules are positioned in the exhaust plenum.

31. The modular platform of claim 16, wherein the first and second fan modules are configured as dual plenum fan modules, having a first portion acting as an intake for an adjacent modular platform and a second portion acting as an exhaust for the modular platform.

32. The modular platform of claim 31, wherein the height of the first and second fan modules is less than or equal to 2 U.
